(19) United States
(12) Patent Application Publication
(10) Pub. No.: US 2012/0273437 A1
(43) Pub. Date: Nov. 1, 2012

(54) ONE OR MORE DEVICE HOLDER

(76) Inventor: Jude Russo, Butler, NJ (US)

(21) Appl. No.: 13/454,530

(22) Filed: Apr. 24, 2012

Related U.S. Application Data
(60) Provisional application No. 61/479,745, filed on Apr. 27, 2011.

(51) Int. Cl. H05K 7/18; A47B 81/00; A47B 96/00

(52) U.S. Cl. 211/26; 211/183; 211/41.1

(57) ABSTRACT

A one or more device holder that includes a generally rectangular base that secures at least one device that is removably secured in an upright position, a first horizontal slot that is disposed across the width of the top portion of the generally rectangular base with a perpendicular supplemental slot disposed on each end of the first horizontal slot and a generally rectangular-shaped vertical backing for the first horizontal slot that is permanently disposed behind the first horizontal slot. The second horizontal slot is disposed on the base behind the first horizontal slot and a third horizontal slot is disposed on the base adjacent to the second horizontal slot behind the first horizontal slot. The one or more device holder may be GPS vehicle holder organizer for any vehicle that turns in to an organizer for office and home.

This application claims priority to U.S. Provisional Application 61/479,745 filed on Apr. 27, 2011, the entire disclosure of which is incorporated by reference.

### TECHNICAL FIELD & BACKGROUND

It is an object of the present invention to provide a one or more device holder that can be utilized inside an office such as a home office, in a boat, on a car seat, on a console in a car, on a desk, clip on a vehicle vent both horizontally and vertically or on a vehicle dashboard. The one or more device holder may be a GPS vehicle holder organizer for any vehicle that turns into an organizer for an office and home An organizer for home and office that can also be used for a vehicle. The outside case for the one or more device holder may also have no slots.

It is an object of the present invention to provide a one or more device holder that can secure a smartphone or other cell phone and/or a GPS device.

It is an object of the present invention to provide a one or more device holder that can secure a MP3 player or a tablet computer such as an IPAD™ or a KINDLE™.

What is really needed is a one or more device holder that can be utilized inside an office such as a home office, on a desk or on a vehicle dashboard that can secure a smartphone or other cell phone and/or a GPS device that can secure a tablet computer such as an IPAD™ or a KINDLE™. The one or more device holder may be one size that can hold all types and sizes of devices and can have one slot or multiple slots.

### BRIEF DESCRIPTION OF THE DRAWINGS

The present invention will be described by way of exemplary embodiments, but not limitations, illustrated in the accompanying drawing in which like references denote similar elements, and in which:

FIG. 1A illustrates a front perspective view of a one or more device holder, in accordance with one embodiment of the present invention.

FIG.-1B illustrates a top view of a one or more device holder, in accordance with one embodiment of the present invention.

FIG. 1C illustrates a top view of a one or more device holder, in accordance with one embodiment of the present invention.

FIG. 2A illustrates a rear perspective view of a one or more device holder, in accordance with one embodiment of the present invention.

FIG. 2B illustrates a rear perspective view of a one or more device holder, in accordance with one embodiment of the present invention.

FIG. 2C illustrates a rear perspective view of a one or more device holder, in accordance with one embodiment of the present invention.

FIG. 2D illustrates a side perspective view of a one or more device holder, in accordance with one embodiment of the present invention.

FIG. 2E illustrates a side perspective view of a one or more device holder, in accordance with one embodiment of the present invention.

FIG. 3A illustrates a side perspective view of a pair of clips attached to the rear of a one or more device holder, in accordance with one embodiment of the present invention.

FIG. 3B illustrates a rear perspective view of a pair of clips attached to the rear of a one or more device holder, in accordance with one embodiment of the present invention.

FIG. 3C illustrates a side perspective view of a plurality of clips attached to a one or more device holder, in accordance with one embodiment of the present invention.

### DETAILED DESCRIPTION OF ILLUSTRATIVE EMBODIMENTS

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention. However, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

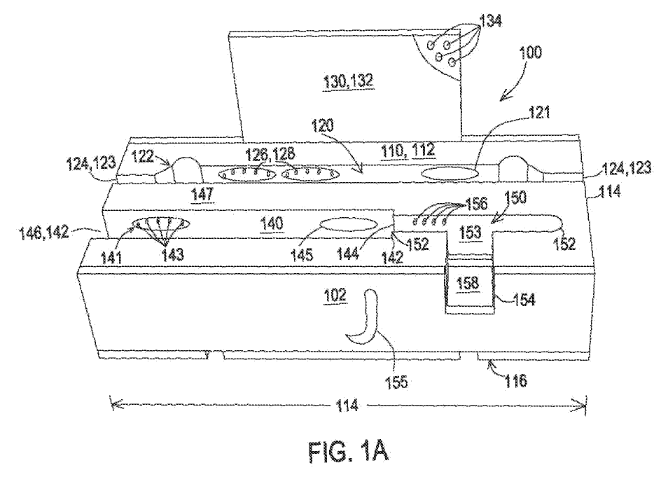

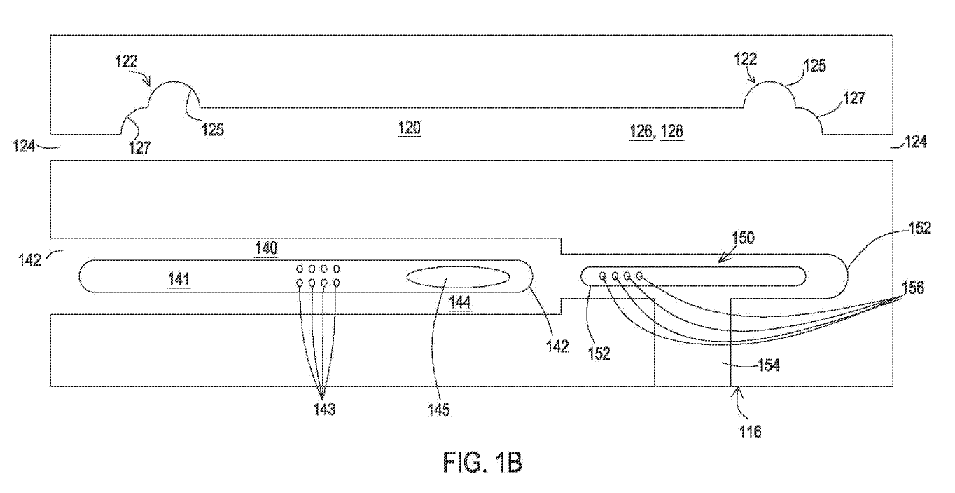

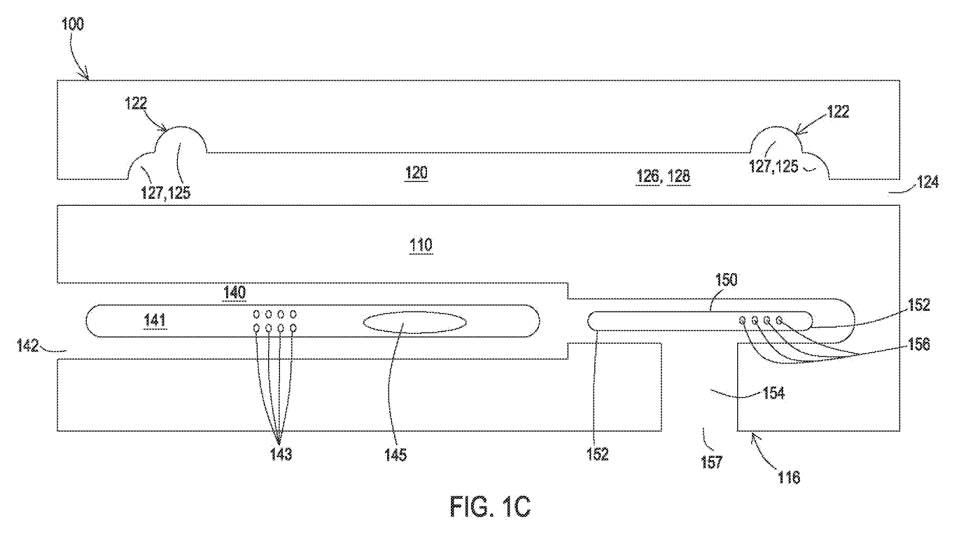

FIG. 1A illustrates a front perspective view of a one or more device holder 100, in accordance with one embodiment of the present invention. The one or more device holder 100 includes a generally rectangular base 110, a first horizontal slot 120, a backing to the first horizontal slot 130, a second horizontal slot 140 and a third horizontal slot 150.

The generally rectangular base 110 serves as a base to secure one or more devices that can be removably secured in an upright position by the one or more device holder 100. The base 110 can be in many different shapes that would allow the various cell phone models on the market or any other devices on the market to be inserted into the single or one or more device holder 100. The generally rectangular base 110 is approximately 3 inches wide, 1½ inches in height and 8 inches in length. The first horizontal slot 120 is disposed on the top portion 112 of the generally rectangular base 110 and runs across an approximate entire width 114 of the generally rectangular base 110. The first horizontal slot 120 is designed to accommodate a suitable tablet computer such as an IPAD™ or a KINDLE™. The first horizontal slot 120 has a perpendicular supplemental slot 122 disposed before each end 124 of the first horizontal slot 120 to accommodate any protruding accessories or permanent parts from the computer tablet being placed in or disposed on the first horizontal slot 120. The perpendicular supplemental slot 122 is approximately ½ inch deep, although the perpendicular supplemental slot 122 can be other suitable depths as well. The ends 124 have an open slot 123 to accommodate and hold relatively longer devices such as an IPAD™, KINDLE™ and other suitable tablet computers. The first horizontal slot 120 has a plurality of apertures 126 disposed on the bottom 128 of the first horizontal slot 120 that can serve to also accommodate any additional protruding accessories or permanent parts from the computer tablet being placed in the first horizontal slot 120. The first horizontal slot 120 can also optionally have a slit 121 disposed on the bottom 128 that allows a battery charger cord (not shown) to run through the slit 121 to the tablet computer. The first horizontal slot 120 is no more than approximately 8 inches in length and is no deeper than approximately ½ inch in depth. The first horizontal slot 120 has a length of no more than approximately 7½ inches and is no deeper than approximately ½ inch. The vertical backing 130 for the first horizontal slot 120 is generally rectangular-shaped 132 and supports the tablet computer being removably placed in the first horizontal slot 120. The vertical backing 130 is permanently disposed behind the first horizontal slot 120 and is slightly non-adjustably tilted backwards at any suitable permanent angle. The vertical backing 130 can also optionally have a plurality of apertures 134.

The second horizontal slot 140 has 2 ends 142 and is disposed in front of the first horizontal slot 120. The second horizontal slot 140 can accommodate and uprightly secure appropriately sized planar items such as papers, sunglasses, a portable satellite radio, business cards or other suitable items that can be removably and uprightly placed in the second horizontal slot 140. The second horizontal slot 140 has an open notch 144 on one end 142 going to the third horizontal slot 150 to accommodate larger devices. There is also an open notch 146 on the other end of the second horizontal slot 140. The second horizontal slot 140 also includes an inner circle 141 with a plurality of apertures 143 disposed on the inner circle 141 that is approximately 1 inch in depth. There is also a slot 145 to accommodate a charging cord (not shown) to allow charging of any stored device. The second horizontal slot 140 is approximately less than ½ inch deep and is approximately 3 inches in width. There is also a top area 147 between the first horizontal slot 120 and the second horizontal slot 140.

The third horizontal slot 150 can accommodate a smartphone such as an IPHONE™ or other suitable planar cell phone or a planar GPS device. The third horizontal slot 150 has two ends 152 and is disposed adjacent to the second horizontal slot 140 behind the first horizontal slot 120 and as previously described has an open notch 144 on one end 152 going to the second horizontal slot 140 to accommodate larger devices. There is a plurality of apertures 156 disposed on the bottom 153 of the third horizontal slot 150 to accommodate any protruding accessories or permanent parts from the smartphone being placed in the first horizontal slot 120. There is also a perpendicular supplemental slot 154 disposed on the middle portion 158 of the third horizontal slot 150 that may be approximately 3 inches long and 1 inch deep that runs to the bottom edge 116 of the generally rectangular base 110 to accommodate a charging cord to charge a smartphone or other suitable device placed in the third horizontal slot 150. There is also an optional hook 155 that can be disposed on the front 102 of the one or more device holder 100 to accommodate hanging a pair of sunglasses (not shown) or other suitable object. The third horizontal slot 150 is approximately 1 inch deep and less than a ½ inch wide and the second horizontal slot 140 is approximately ¼ of an inch wide.

FIG.-1B illustrates a top view of a one or more device holder 100, in accordance with one embodiment of the present invention. FIG. 1B illustrates and describes all of the similar elements that were previously illustrated and described in FIG. 1A except the backing to the first horizontal slot 130 that is disposed behind the first horizontal slot 120. These similar components include the generally rectangular base 110, the first horizontal slot 120, the second horizontal slot 140 and the third horizontal slot 150, as well as the similar components supplemental features and dimensions described and illustrated in FIG. 1B and its description.

FIG. 1C illustrates a top view of a one or more device holder 100, in accordance with one embodiment of the present invention. FIG. 1C illustrates and describes all of the similar elements that were previously illustrated and described in FIG. 1B except the third horizontal slot 150 is accessible and in physical communication with the perpendicular supplemental slot 154 that is disposed on the bottom edge 116 of the generally rectangular base 110. These similar components include the generally rectangular base 110, the first horizontal slot 120, the second horizontal slot 140 and the other third horizontal slot 150, as well as the similar components' supplemental features and dimensions. There is also an open slot 157 leading from perpendicular supplemental slot 154 to allow for a device to slide directly out of the third horizontal slot 150.

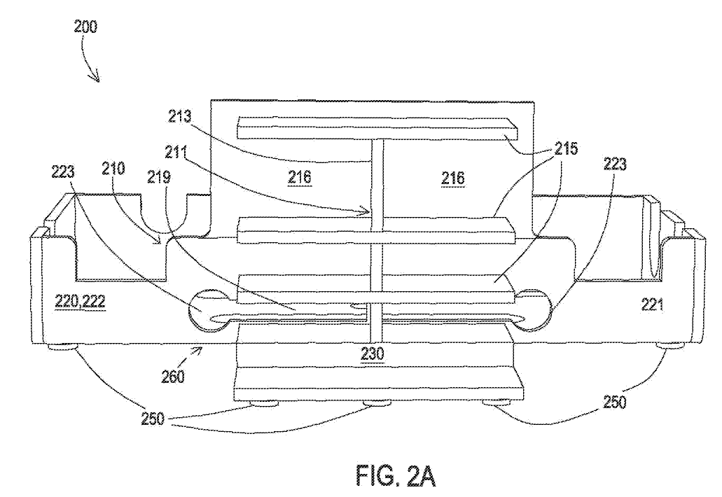

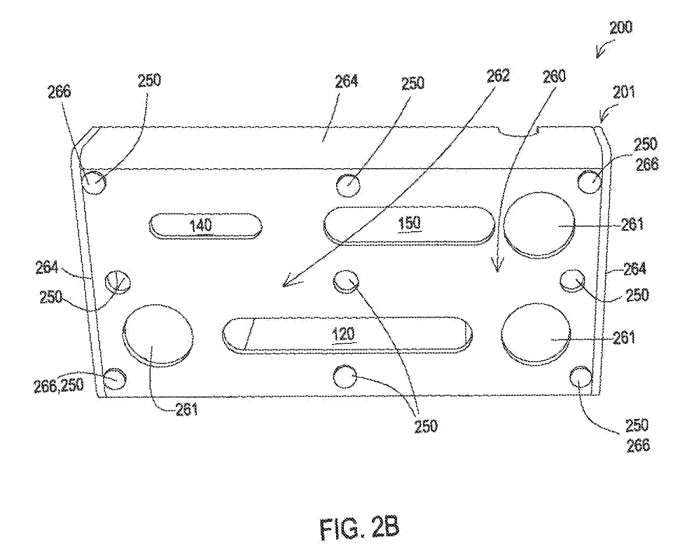

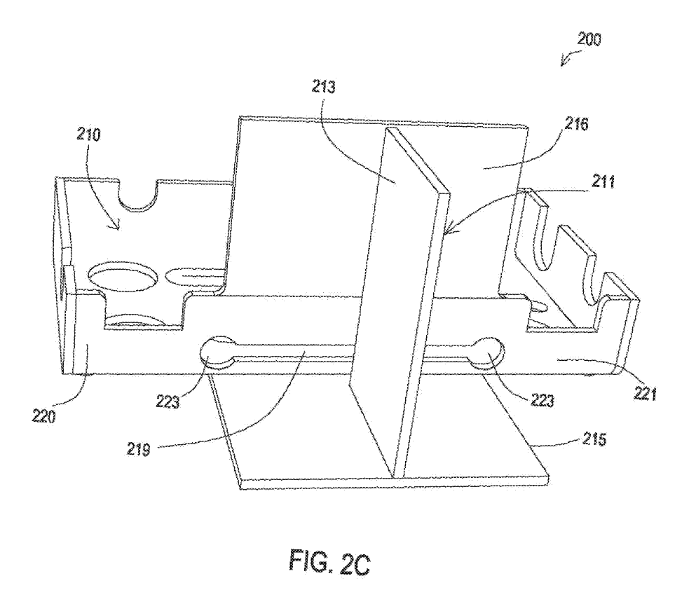

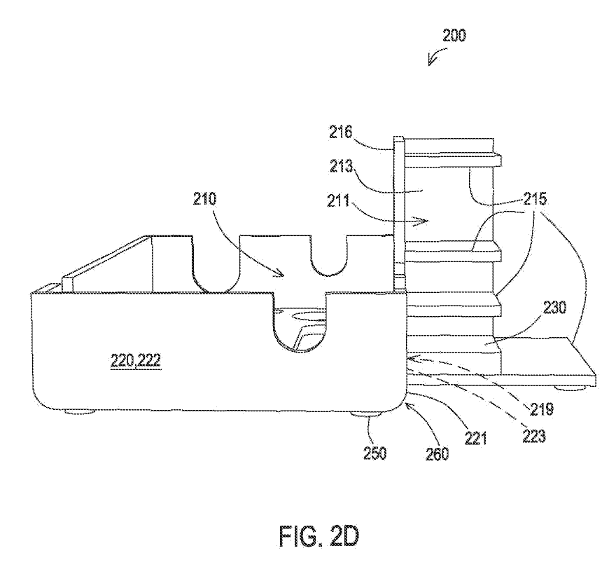

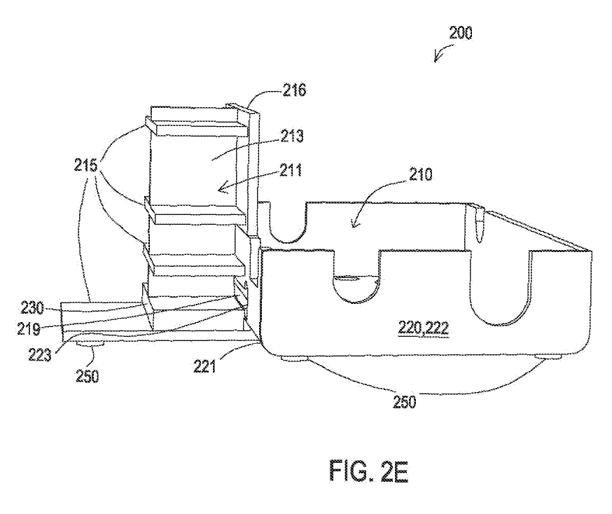

FIG. 2A illustrates a rear perspective view of a one or more device holder 200, in accordance with one embodiment of the present invention. The one or more device holder 200 has similar features as the one or more device holder 100 illustrated and described in the FIG. 1A, but in contrast has some differences.

The one or more device holder 200 includes an open interior 210, a plurality of perimeter walls 220 and a rear attachment block 230. The perimeter walls 220 include a back wall 221 and completely encompass the entire perimeter 222 of the open interior 210 of the one or more device holder 200. The rear attachment block 230 is attached to a back wall 221 of the perimeter walls 220. The one or more device holder 200 includes a T-shaped protruding support 211 with a vertical support 213 and one or more additional shelves 215, the backing to the first horizontal slot 216, a slot 219 with a pair of circular ends 223 and a plurality of suction cups 250 disposed on the bottom surface 260. FIG. 2B illustrates a rear perspective view of a one or more device holder 200, in accordance with one embodiment of the present invention. The one or more device holder 200 has similar features as the one or more device holder 100 illustrated and described in FIG. 1A, but in contrast has some differences. A shell 201 may be made of plastic, tin, aluminum or any other metal. The shell 201 has the first horizontal slot 120 the second horizontal slot 140 and the other third horizontal slot 150 that allow for a charging cord for the device in the one or more device holder 200. The shell 201 may be a changing station for your car or home or office. A plurality of suction cups 250 can be disposed on the bottom surface 260 of the one or more device holder 200 and are disposed on the bottom surface 260, but can be disposed on any suitable area or in any suitable quantity on the bottom surface 260 of the one or more device holder 200 such as on the sides 264 or the corners 266 of the bottom surface 260. The suction cups 250 as illustrated in FIG. 2B are disposed on the sides 264 of, the corners 266 of, or the middle portion 262 of the bottom surface 260. 3 apertures 261 are disposed on the bottom surface 260 for ventilation and to reduce the overall weight of the shell 201 however any quantity of apertures 261 can be disposed on the bottom surface 260.

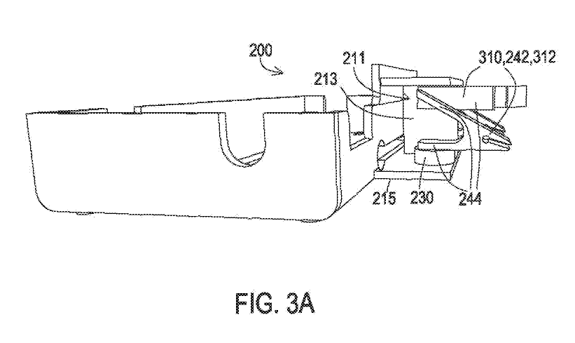

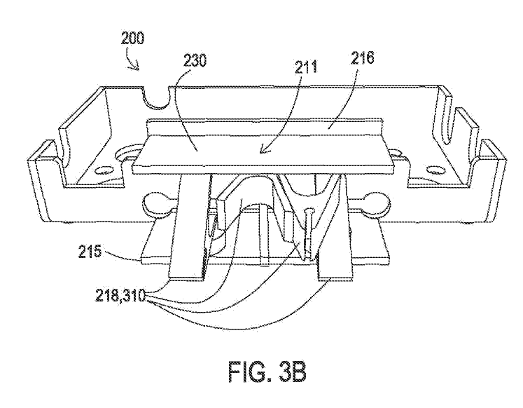

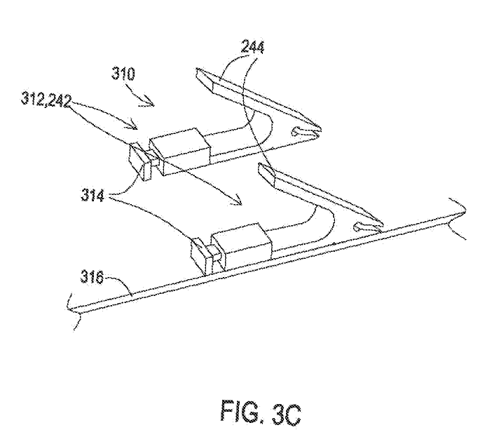

FIG. 2C illustrates a rear perspective view of a one or more device holder 200, in accordance with one embodiment of the present invention. FIG. 2C illustrates and describes all of the similar elements that were previously illustrated and described in FIG. 2A except the T-shaped protruding support 211 that is disposed behind the backing to the first horizontal slot 216 (the T-shaped protruding support 211 may have one or more additional shelves 215 to give support for the clips (FIG. 3, 310)). These similar components include the open interior 210, the backing to the first horizontal slot 216, the plurality of perimeter walls 220 that include the back wall 221, and a slot 219 with a pair of circular ends 223.

FIG. 2D illustrates a side perspective view of a one or more device holder 200, in accordance with one embodiment of the present invention. The one or more device holder 200 includes all of the elements of the one or more device holder 200 illustrated and described in FIG. 2A that include an open interior 210, a plurality of perimeter walls 220 and a rear attachment block 230. The perimeter walls 220 include a back wall 221 and completely encompass the entire perimeter 222 of the open interior 210 of the one or more device holder 200. The rear attachment block 230 is attached to a back wall 221 of the perimeter walls 220. The one or more device holder 200 includes a T-shaped protruding support 211 with a vertical support 213 and one or more additional shelves 215, the backing to the first horizontal slot 216, a slot 219 with a pair of circular ends 223 and a plurality of suction cups 250 disposed on the bottom surface 260.

FIG. 2E illustrates a side perspective view of a one or more device holder, in accordance with one embodiment of the present invention. The one or more device holder 200 includes all of the elements of the one or more device holder 200 illustrated and described in FIG. 2A that include an open interior 210, a plurality of perimeter walls 220 and a rear attachment block 230. The perimeter walls 220 include a back wall 221 and completely encompass the entire perimeter 222 of the open interior 210 of the one or more device holder 200. The rear attachment block 230 is attached to a back wall 221 of the perimeter walls 220. The one or more device holder 200 includes a T-shaped protruding support 211 with a vertical support 213 and one or more additional shelves 215, the backing to the first horizontal slot 216, a slot 219 with a pair of circular ends 223 and a plurality of suction cups 250 disposed on the bottom surface 260.

FIG. 3A illustrates a side perspective view of a plurality of clips 310, in accordance with one embodiment of the present invention. The clips 310 include a pair of clips 310 that are a double ended clips 242 with an attached backing 244 that can secure the double ended clips 242 of the one or more device holder 200 to a vent (not shown) to removably attach to the T-shaped protruding support 211 and the rear attachment block 230 while removably attaching the one or more device holder 200 to any other suitable surface such as a dashboard (not shown). The pair of clips 310 can be one or more of any suitable clips such as one or more double ended clips 242 or extendable clips 312. Clips 310 can be any suitable clip that can attach to the a car vent or a CD slot of a CD player (not shown) and to the T-shaped protruding support 211 and its vertical support 213 and may have support for one or more additional shelves 215. The one or more additional shelves 215 may be used to insert into a CD player to support and hold the one or more device holder 200.

FIG. 3B illustrates a rear perspective view of a pair of clips 310 attached to the rear of a one or more device holder 200, in accordance with one embodiment of the present invention. More specifically, the pair of attachment clips 310 is removably attached to the backing to the first horizontal slot 216 with a pair of attachment plugs 218 and the T-shaped protruding support 211 with a vertical support 213 while removably attaching the one or more device holder 200 to any other suitable surface such as a dashboard (not shown).

FIG. 3C illustrates a side perspective view of a plurality of clips 310 attached to a one or more device holder, in accordance with one embodiment of the present invention.

The pair of clips 310 can be any suitable clips such as one or more double ended clips 242 or extendable clips 312 with an attached backing 244, a pair of knobs 314 and a wire 316 that is attached to pair of clips 310. Clips 310 may be bendable to support on various angles the one or more device holder and the clips 310 can be various shapes.

The one or more device holder may be made of foam, rubber or plastic material, although the one or more device holder can be made of any suitable material or combination of materials. The one or more device holder can be utilized inside an office such as a home office, on a desk, on a vehicle dashboard, in any other suitable area or environment or the one or more device holder may be a GPS vehicle holder organizer that turns into an office and home organizer. One or more hook and loop fastener strips can secure the one or more device holder to a vehicle dashboard or a plurality of attachment for extend clips can secure the one or more device holder to a vent. The one or more device holder is approximately 3 inches wide, 8 inches long and 1½ inches in height, although the one or more device holder can have any suitable dimensions. In one embodiment the one or more device holders will have a plurality of apertures on the back to accommodate clips that will allow the one or more device holders to attach to a vent of a car.

While the present invention has been related in terms of the foregoing embodiments, those skilled in the art will recognize that the invention is not limited to the embodiments described. The present invention can be practiced with modification and alteration within the spirit and scope of the appended claims. Thus, the description is to be regarded as illustrative instead of restrictive on the present invention.

1. A one or more device holder, comprising:
a base;
at least one horizontal slot to accommodate at least one device removably stored uprightly in said horizontal slot; and
a vertical backing disposed behind said at least one said horizontal slot.

2. The holder according to claim 1, wherein said at least one horizontal slot includes a first horizontal slot, a second horizontal slot and a third horizontal slot.

3. The holder according to claim 2, wherein said first horizontal slot accommodates and removably secures a tablet computer in an upright position.

4. The holder according to claim 2, wherein said second horizontal slot accommodates and removably secures at least one planar item that include at least one tablet computer in an upright position.

5. The holder according to claim 2, wherein said third horizontal slot accommodates and removably secures a device selected from the group consisting of a smartphone, a planar cell phone or a planar GPS device in an upright position.

6. The holder according to claim 2, wherein said vertical backing is disposed behind said first vertical slot.

7. A one or more device holder, comprising:
a generally rectangular base with a top portion that secures at least one device that is removably secured in an upright position;
a first horizontal slot with two ends that is disposed on said top portion of said generally rectangular base;
a generally rectangular-shaped vertical backing to said first horizontal slot that is permanently disposed behind said first horizontal slot;
a second horizontal slot disposed on said base behind said first horizontal slot; and
a third horizontal slot disposed on said base adjacent to said second horizontal slot behind said first horizontal slot.

8. The holder according to claim 7, wherein said first horizontal slot accommodates and removably secures a tablet computer in an upright position.

9. The holder according to claim 7, wherein said second horizontal slot accommodates and removably secures at least one planar item that include a GPS device, a cell phone or an MP3 device.

10. The holder according to claim 7, wherein said third horizontal slot accommodates and removably secures a device selected from the group consisting of a smartphone, a planar cell phone or a planar GPS device in an upright position.

11. The holder according to claim 7, wherein said first horizontal slot has a perpendicular supplemental slot disposed on each end of said first horizontal slot.

12. The holder according to claim 7, wherein said vertical backing is non-adjustably tilted backwards at a permanent angle.

13. A one or more device holder with a front, comprising:
a generally rectangular base with a top portion and a width that secures at least one device that is removably secured in an upright position;
a first horizontal slot with two ends and a bottom that is disposed across said width of said top portion of said generally rectangular base that accommodates and removably secures a tablet computer in an upright position with a perpendicular supplemental slot disposed on each said end of said first horizontal slot, wherein a slit is disposed on said bottom that allows a battery charger cord to run through said slit to said tablet computer;
a generally rectangular-shaped vertical backing to said first horizontal slot that is permanently disposed behind said first horizontal slot;
a second horizontal slot disposed on said base behind said first horizontal slot;
a third horizontal slot with a bottom disposed on said base adjacent to said second horizontal slot behind said first horizontal slot;
an open interior with a plurality of perimeter walls enclosing said slots; and
a T-shaped protruding support that is disposed behind said backing of said first horizontal slot that includes a rear attachment block and a second shelf that allows attaching at least one extended product.

14. The holder according to claim 13, wherein a first plurality of apertures is disposed on said bottom of said first horizontal slot.

15. The holder according to claim 13, wherein said vertical backing is non-adjustably tilted backwards at a permanent angle and has a plurality of apertures.

16. The holder according to claim 13, wherein said second horizontal slot accommodates and removably secures at least one planar item that include at least one papers and cards in an upright position.

17. The holder according to claim 13, wherein said third horizontal slot accommodates and removably secures a device selected from the group consisting of a smartphone, a planar cell phone or a planar GPS device in an upright position.

18. The holder according to claim 13, wherein a second plurality of apertures is disposed on said bottom of said third horizontal slot.

19. The holder according to claim 13, wherein said at least one extended product include at least one attachment clip.

20. The holder according to claim 13, wherein said one or more device holder is a GPS vehicle holder organizer that turns in to an office and home organizer.
